(19) United States
(12) Patent Application Publication
(10) Pub. No.: US 2024/0224667 A1
(43) Pub. Date: Jul. 4, 2024

(54) DISPLAY DEVICE

(71) Applicant: LG Display Co., Ltd, Seoul (KR)

(72) Inventors: MinSeok KIM, Paju-si (KR); Hun JANG, Paju-si (KR)

(73) Assignee: LG Display Co., Ltd, Seoul (KR)

(21) Appl. No.: 18/532,447

(22) Filed: Dec. 7, 2023

(30) Foreign Application Priority Data
Dec. 28, 2022 (KR) 10-2022-0187118

(51) Int. Cl. H10K 59/131; H10K 59/12; H10K 59/123; H10K 59/126; H10K 59/80; H10K 71/60

(52) U.S. Cl. CPC H10K 59/131; H10K 59/1201; H10K 59/123; H10K 59/126; H10K 59/878; H10K 71/60

(57) ABSTRACT

According to an aspect of the present disclosure, a display device includes: a substrate including a plurality of sub-pixels; a first line and a second line disposed in the plurality of sub-pixels on the substrate and separated from each other; a passivation layer covering the first line and the second line; a light-emitting element on the passivation layer above the first line and the second line; and a metal layer between the passivation layer and the light-emitting element and connected to the first line and the second line.

### CROSS-REFERENCE TO RELATED APPLICATIONS

This application claims the priority of Korean Patent Application No. 10-2022-0187118 filed on Dec. 28, 2022, in the Korean Intellectual Property Office, the disclosure of which is incorporated herein by reference.

### TECHNICAL FIELD

The present disclosure relates to a display device, and more particularly, to a display device in which a light-emitting diode (LED) is self-assembled.

### BACKGROUND

As display devices used for a monitor of a computer, a TV set, a mobile phone, and the like, there are an organic light-emitting display (OLED) configured to autonomously emit, and a liquid crystal display (LCD) that requires a separate light source.

The display devices are diversified and may be implemented used the monitor of the computer, a TV set, and a screen for personal mobile devices. Studies are being conducted on the display devices having wide display areas and having reduced volume and weight.

In addition, recently, a display device including a LED has attracted attention as a next-generation display device. Because the LED is made of an inorganic material instead of an organic material, the LED is more reliable and has a longer lifespan than a liquid crystal display device or an organic light-emitting display device. In addition, the LED may be quickly turn on or off, have excellent luminous efficiency, high impact resistance, great stability, and display high-brightness images.

### SUMMARY

An object to be achieved by the present disclosure is to provide a display device comprising self-assembled light-emitting element.

Another object to be achieved by the present disclosure is to provide a display device in which the amount of light in a forward direction is increased, thereby improving luminous efficiency.

Objects of the present disclosure are not limited to the above-mentioned objects, and other objects, which are not mentioned above, may be clearly understood by those skilled in the art from the following descriptions.

According to an aspect of the present disclosure, a display device includes: a substrate including a plurality of sub-pixels: a first line and a second line disposed in the plurality of sub-pixels on the substrate and spaced apart from each other: a passivation layer covering the first line and the second line: a light-emitting element on the passivation layer above the first line and the second line, and including a first electrode, a first semiconductor layer, a light-emitting layer, a second semiconductor layer, and a second electrode; and a metal layer between the passivation layer and the light-emitting element and connected to the first line and the second line.

Other detailed matters of the aspects are included in the detailed description and the drawings.

According to the aspect of the present disclosure, it is possible to improve light extraction efficiency by increasing the amount of light directed in the direction of the front surface of the light-emitting element.

According to the aspect of the present disclosure, the metal layer may be disposed below the self-assembled light-emitting element, thereby increasing an assembling force of the light-emitting element during a subsequent process.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an aspect of the present disclosure:

FIG. 2A is an enlarged top plan view of the display device according to the aspect of the present disclosure:

FIG. 2B is a cross-sectional view taken along lines A-A′ and B-B′ in FIG. 2A:

FIGS. 3A to 3E are views for explaining a process of manufacturing the display device according to the aspect of the present disclosure:

FIG. 4 is a cross-sectional view of a display device according to another aspect of the present disclosure:

FIG. 5 is a cross-sectional view of a display device according to still another aspect of the present disclosure:

FIG. 6 is a cross-sectional view of a display device according to yet another aspect of the present disclosure:

FIGS. 7A to 7E are views for explaining a process of manufacturing the display device according to yet another aspect of the present disclosure: and

FIG. 8 is a cross-sectional view of a display device according to still yet another aspect of the present disclosure.

### DETAILED DESCRIPTION

Advantages and characteristics of the present disclosure and a method of achieving the advantages and characteristics will be clear by referring to aspects described below in detail together with the accompanying drawings. However, the present disclosure is not limited to the aspects disclosed herein but will be implemented in various forms. The aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the aspects of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, the present disclosure will be described in detail with reference to accompanying drawings.

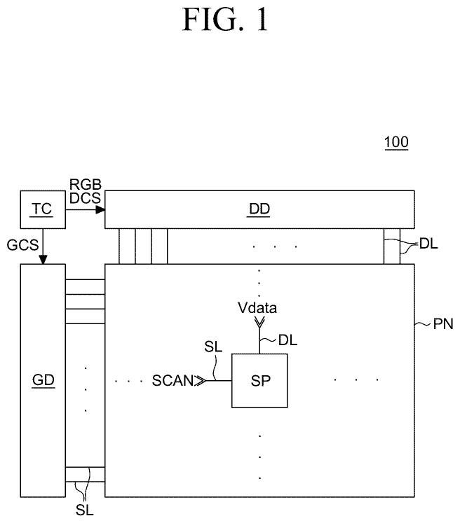

FIG. 1 is a schematic configuration view of a display device according to an aspect of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub-pixels SP, the gate drive part GD configured to supply various types of signals to the display panel PN, and the timing controller TC configured to control the data drive part DD, the gate drive part GD, the data drive part DD.

The display panel PN is configured to display images to a user by controlling the plurality of sub-pixels SP. In the display panel PN, the plurality of scan lines SL, and the plurality of data lines DL intersect one another, and each of the plurality of sub-pixels SP is connected to the scan line SL and the data line DL. In addition, although not illustrated in the drawings, the plurality of sub-pixels SP may be respectively connected to a high-potential power line, a low-potential power line, a reference line, and the like.

The plurality of sub-pixels SP each include a light emitting element and a pixel circuit for driving the light emitting element. The plurality of light emitting elements may have different configurations depending on the type of display panel PN. For example, in case that the display panel PN is an inorganic light-emitting display panel, the light-emitting element may be a light-emitting diode (LED) or a micro LED.

The gate drive part GD supplies a plurality of scan signals SCAN to a plurality of scan lines SL in response to a plurality of gate control signals GCS provided from the timing controller TC. FIG. 1 illustrates that the single gate drive part GD is disposed to be spaced apart from one side of the display panel PN. However, the number of and arrangement of the gate drive part GD are not limited thereto.

The data drive part DD converts image data RGB, which provided from the timing controller TC, in response to a plurality of data control signals DCS provided from the timing controller TC, into a data voltage Vdata by using a reference gamma voltage. The data drive part DD may supply the converted data voltage Vdata to the plurality of data lines DL.

The timing controller TC aligns the image data RGB, which are inputted from the outside, and supplies the image data RGB to the data drive part DD. The timing controller TC may create the gate control signals GCS and the data control signals DCS using synchronization signals, for example, dot clock signals, data enable signals, and horizontal/vertical synchronizing signals inputted from the outside. Further, the timing controller TC may control the gate drive part GD and the data drive part DD by supplying the generated gate control signals GCS and the generated data control signals DCS to the gate drive part GD and the data drive part DD.

The plurality of sub-pixels SP of the display panel PN of the display device 100 according to the aspect of the present disclosure disclosure will be described in more detail.

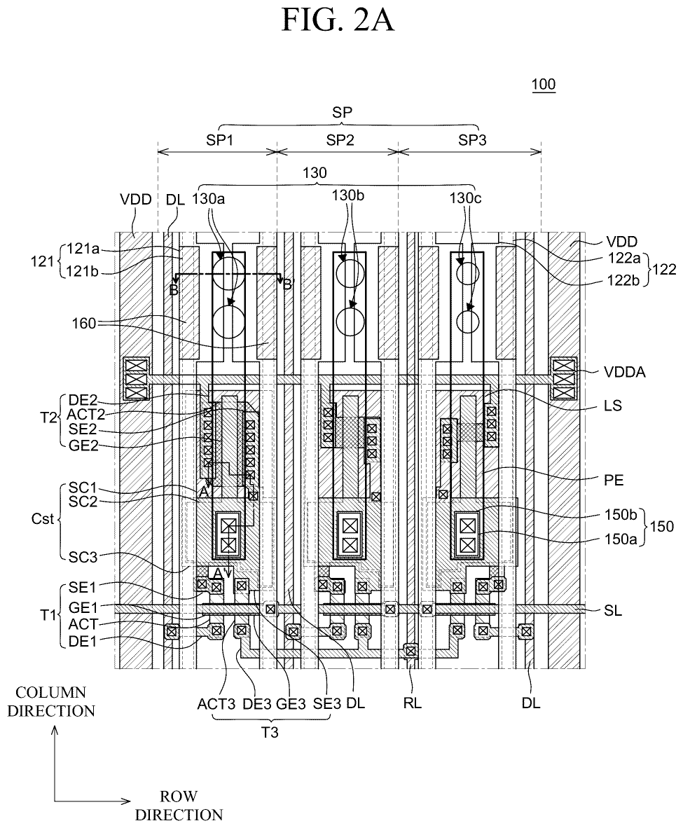

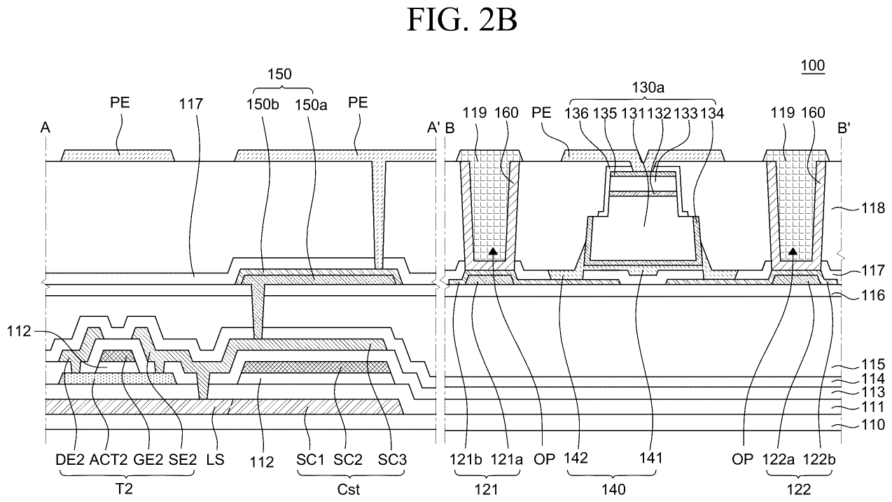

FIG. 2A is an enlarged top plan view of the display device according to the aspect of the present disclosure. FIG. 2B is a cross-sectional view taken along lines A-A′ and B-B′ in FIG. 2A. With reference to FIG. 2A, the plurality of sub-pixels SP each includes a first transistor T1, a second transistor T2, a third transistor T3, a storage capacitor Cst, and one or more light-emitting elements 130. For convenience of description, in FIG. 2A, hatching patterns of a first line 121, a second line 122, the light-emitting element 130, a reflective layer 160, and a pixel electrode PE is omitted. Further, a metal layer 140 is omitted to improve visibility of the illustration.

With reference to FIGS. 2A and 2B, the plurality of sub-pixels SP includes a first sub-pixel SP1, a second sub-pixel SP2, and a third sub-pixel SP3. The first sub-pixel SP1, the second sub-pixel SP2, and the third sub-pixel SP3 may each include the light-emitting element 130 and a circuit configured to independently emit light. For example, the first sub-pixel SP1 may be a red sub-pixel, the second sub-pixel SP2 may be a green sub-pixel, and the third sub-pixel SP3 may be a blue sub-pixel. However, the present disclosure is not limited thereto.

The display panel PN includes a substrate 110, a buffer layer 111, a gate insulation layer 112, an interlayer insulation layer 113, a first passivation layer 114, a first planarization layer 115, a second passivation layer 116, a third passivation layer 117, and a second planarization layer 118.

The substrate 110 supports various constituent elements included in the display device 100 and may be made of an insulating material. For example, the substrate 110 may be made of glass, resin, or the like. In other aspects, the substrate 110 may include flexible material such as a plastic (e.g., a polymer).

A high-potential power line VDD, the plurality of data lines DL, a reference line RL, a light-blocking layer LS, and a first capacitor electrode SC1 are disposed on the substrate 110.

The high-potential power line VDD transmits a high-potential power voltage to each of the plurality of sub-pixels SP. The plurality of high-potential power lines VDD may each transmit the high-potential power voltage to the second transistor T2 of each of the plurality of sub-pixels SP. The high-potential power line VDD may extend in a column direction between the plurality of sub-pixels SP. For example, the high-potential power line VDD may be disposed in the column direction between the first sub-pixel SP1 and the third sub-pixel SP3. Further, the high-potential power line VDD may transmit the high-potential power voltage to each of the plurality of sub-pixels SP disposed in a row direction through an auxiliary high-potential power line VDDA to be described below.

The plurality of data lines DL transmit the data voltage Vdata to each of the plurality of sub-pixels SP. The plurality of data lines DL may each be connected to the first transistor T1 of each of the plurality of sub-pixels SP. The plurality of data lines DL may extend in the column direction between the plurality of sub-pixels SP. For example, the data line DL, which extends in the column direction between the first sub-pixel SP1 and the high-potential power line VDD, may transmit the data voltage Vdata to the first sub-pixel SP1. The data line DL disposed between the first sub-pixel SP1 and the second sub-pixel SP2 may transmit the data voltage Vdata to the second sub-pixel SP2. The data line DL disposed between the third sub-pixel SP3 and the high-potential power line VDD may transmit the data voltage Vdata to the third sub-pixel SP3.

The reference line RL transmits a reference voltage to each of the plurality of sub-pixels SP. The reference line RL may be connected to the third transistor T3 of each of the plurality of sub-pixels SP. The reference line RL may extend in the column direction between the plurality of sub-pixels SP. For example, the reference line RL may extend in the column direction between the second sub-pixel SP2 and the third sub-pixel SP3. Further, a third drain electrode DE3 of the third transistor T3 of each of the first sub-pixel SP1, the second sub-pixel SP2, and the third sub-pixel SP3 disposed adjacent to the reference line RL may extend in the row direction and be electrically connected to the reference line RL.

The light-blocking layer LS may be provided on each of the plurality of sub-pixels SP and disposed on the substrate 110. The light-blocking layer LS may block light, which enters the transistor from a lower side of the substrate 110 and minimize light leakage. For example, the light-blocking layer LS may block light entering a second active layer ACT2 of the second transistor T2.

The first capacitor electrode SC1 is provided on each of the plurality of sub-pixels SP and disposed on the substrate 110. The first capacitor electrode SC1, together with other capacitor electrodes, may form the storage capacitor Cst. The first capacitor electrode SC1 may be integrated with the light-blocking layer LS.

The buffer layer 111 is disposed on the high-potential power line VDD, the plurality of data lines DL, the reference line RL, the light-blocking layer LS, and the first capacitor electrode SC1. The buffer layer 111 may reduce the penetration of moisture or impurities within the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

First, the first transistor T1 is provided on each of the plurality of sub-pixels SP and disposed on the buffer layer 111. The first transistor T1 is configured to transmit the data voltage Vdata to a second gate electrode GE2 of the second transistor T2. The first transistor T1 may be turned on by the scan signal SCAN from the scan line SL. The data voltage Vdata from the data line DL may be transmitted to the second gate electrode GE2 of the second transistor T2 through the first transistor T1 when turned on. Therefore, the first transistor T1 may be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be made of a semiconductor material such as an oxide semiconductor, amorphous silicon, or polysilicon. However, the present disclosure is not limited thereto.

The gate insulation layer 112 is disposed on the first active layer ACT1. The gate insulation layer 112 insulates the first active layer ACT1 and the first gate electrode GE1. The gate insulation layer 112 may be configured as a single layer or multilayer made of silicon oxide (SiOx) or silicon nitride (SiNx). However, the present disclosure is not limited thereto.

The first gate electrode GE1 is disposed on the gate insulation layer 112. The first gate electrode GE1 may be electrically connected to the scan line SL. The first gate electrode GE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The interlayer insulation layer 113 is disposed on the first gate electrode GE1. A contact hole is formed in the interlayer insulation layer 113 so that the first source electrode SE1 and the first drain electrode DE1 are each connected to the first active layer ACT1. The interlayer insulation layer 113 may be an insulation layer for protecting components disposed below the interlayer insulation layer 113. The interlayer insulation layer 113 may be configured as a single layer or multilayer made of silicon oxide (SiOx) or silicon nitride (SiNx). However, the present disclosure is not limited thereto.

The first source electrode SE1 and the first drain electrode DE1 are disposed on the interlayer insulation layer 113 and electrically connected to the first active layer ACT1. The first drain electrode DE1 may be connected to the data line DL and the first active layer ACT1. The first source electrode SE1 may be connected to the first active layer ACT1 and the second gate electrode GE2 of the second transistor T2. The first source electrode SE1 and the first drain electrode DE1 may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The second transistor T2 is provided on each of the plurality of sub-pixels SP and disposed on the buffer layer 111. The second transistor T2 is configured to supply a drive current to the light-emitting element 130. The second transistor T2 may be turned on and control the drive current flowing to the light-emitting element 130. Therefore, the second transistor T2, which controls the drive current, may be referred to as a driving transistor.

The second transistor T2 includes the second active layer ACT2, the second gate electrode GE2, a second source electrode SE2, and a second drain electrode DE2.

The second active layer ACT2 is disposed on the buffer layer 111. The second active layer ACT2 may be made of a semiconductor material such as an oxide semiconductor, amorphous silicon, or polysilicon. However, the present disclosure is not limited thereto.

The gate insulation layer 112 is disposed on the second active layer ACT2, and the second gate electrode GE2 is disposed on the gate insulation layer 112. The second gate electrode GE2 may be electrically connected to the first source electrode SE1 of the first transistor T1. The second gate electrode GE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The interlayer insulation layer 113 is disposed on the second gate electrode GE2. The second source electrode SE2 and the second drain electrode DE2 are disposed on the interlayer insulation layer 113 and electrically connected to the second active layer ACT2. The second drain electrode DE2 may be electrically connected to the second active layer ACT2 and the high-potential power line VDD. The second source electrode SE2 may be electrically connected to the second active layer ACT2 and the light-emitting element 130. The second source electrode SE2 and the second drain electrode DE2 may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The third transistor T3 is provided on each of the plurality of sub-pixels SP and disposed on the buffer layer 111. The third transistor T3 is is configured to compensate for a threshold voltage of the second transistor T2. The third transistor T3 is connected between the reference line RL and the second source electrode SE2 of the second transistor T2. The third transistor T3 may be turned on, transmit a reference voltage to the second source electrode SE2 of the second transistor T2, and sense the threshold voltage of the second transistor T2. Therefore, the third transistor T3 senses the properties of the second transistor T2 and may be referred to as a sensing transistor.

The third transistor T3 includes a third active layer ACT3, a third gate electrode GE3, a third source electrode SE3, and the third drain electrode DE3.

The third active layer ACT3 is disposed on the buffer layer 111. The third active layer ACT3 may be made of a semiconductor material such as an oxide semiconductor, amorphous silicon, or polysilicon. However, the present disclosure is not limited thereto.

The gate insulation layer 112 is disposed on the third active layer ACT3, and the third gate electrode GE3 is disposed on the gate insulation layer 112. The third gate electrode GE3 may be electrically connected to the scan line SL. The third gate electrode GE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The interlayer insulation layer 113 is disposed on the third gate electrode GE3. The third source electrode SE3 and the third drain electrode DE3 are disposed on the interlayer insulation layer 113 and electrically connected to the third active layer ACT3. The third drain electrode DE3 may be electrically connected to the third active layer ACT3 and the reference line RL. The third source electrode SE3 may be electrically connected to the second source electrode SE2 of the second transistor T2 and the third active layer ACT3. The third source electrode SE3 and the third drain electrode DE3 may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

In some aspects, a second capacitor electrode SC2 is disposed on the gate insulation layer 112. The second capacitor electrode SC2 may be one of the electrodes that constitute the storage capacitor Cst. The second capacitor electrode SC2 may be disposed to overlap the first capacitor electrode SC1. The second capacitor electrode SC2 may be integrated with the second gate electrode GE2 of the second transistor T2 and electrically connected to the second gate electrode GE2. The first capacitor electrode SC1 and the second capacitor electrode SC2 may be disposed to be spaced apart from each other with the buffer layer 111 and the gate insulation layer 112 interposed therebetween.

Further, the plurality of scan lines SL, the auxiliary high-potential power line VDDA, and a third capacitor electrode SC3 are disposed on the interlayer insulation layer 113.

The scan line SL transmits the scan signal SCAN to each of the plurality of sub-pixels SP. The scan line SL may extend in the row direction while traversing the plurality of sub-pixels SP. The scan line SL may be electrically connected to the first gate electrode GE1 of the first transistor T1 and the third gate electrode GE3 of the third transistor T3 of each of the plurality of sub-pixels SP.

The auxiliary high-potential power line VDDA is disposed on the interlayer insulation layer 113. The auxiliary high-potential power line VDDA may extend in the row direction and be disposed while traversing the plurality of sub-pixels SP. The auxiliary high-potential power line VDDA may be electrically connected to the high-potential power line VDD that extends in the column direction. The auxiliary high-potential power line VDDA may be electrically connected to the second drain electrode DE2 of the second transistor T2 of each of the plurality of sub-pixels SP disposed in the row direction.

The third capacitor electrode SC3 is disposed on the interlayer insulation layer 113. The third capacitor electrode SC3 may be an electrode that constitutes the storage capacitor Cst. The third capacitor electrode SC3 may be disposed to overlap the first capacitor electrode SC1 and the second capacitor electrode SC2. The third capacitor electrode SC3 may be integrated with the second source electrode SE2 of the second transistor T2 and electrically connected to the second source electrode SE2. Further, the second source electrode SE2 may also be electrically connected to the first capacitor electrode SC1 through contact holes formed in the interlayer insulation layer 113 and the buffer layer 111. In this case, the first capacitor electrode SC1 and the third capacitor electrode SC3 may be electrically connected to the second source electrode SE2 of the second transistor T2.

The storage capacitor Cst may store a potential difference between the second gate electrode GE2 and the second source electrode SE2 of the second transistor T2 while the light-emitting element 130 emits light, such that a constant electric current may be supplied to the light-emitting element 130. The storage capacitor Cst is formed on the substrate 110 and formed on the first capacitor electrode SC1, the buffer layer 111, and the gate insulation layer 112 connected to the second source electrode SE2. The storage capacitor Cst is formed on the second capacitor electrode SC2 and the interlayer insulation layer 113 connected to the second gate electrode GE2 and includes the third capacitor electrode SC3 connected to the second source electrode SE2. The storage capacitor Cst may store a voltage between the second gate electrode GE2 and the second source electrode SE2 of the second transistor T2.

The first passivation layer 114 is disposed on the first transistor T1, the second transistor T2, the third transistor T3, and the storage capacitor Cst. The first passivation layer 114 may insulate and protect components disposed below the first passivation layer 114. The first passivation layer 114 may be configured as a single layer or multilayer made of silicon oxide (SiOx) or silicon nitride (SiNx). However, the present disclosure is not limited thereto.

The first planarization layer 115 is disposed on the first passivation layer 114. The first planarization layer 115 may planarize an upper portion of the substrate 110 on which the plurality of transistors T1, T2, and T3 and the storage capacitor Cst are disposed. The first planarization layer 115 may be configured as a single layer or multilayer and made of an acrylic-based organic material, for example. However, the present disclosure is not limited thereto.

The second passivation layer 116 is disposed on the first planarization layer 115. The second passivation layer 116 may be an insulation layer for protecting components disposed below the second passivation layer 116. The second passivation layer 116 may be configured as a single layer or multilayer made of silicon oxide (SiOx) or silicon nitride (SINx). However, the present disclosure is not limited thereto.

A connection part 150, the first line 121, and the second line 122 are disposed on the second passivation layer 116.

In one aspect, the connection part 150 is disposed on each of the plurality of sub-pixels SP. The connection part 150 is an electrode that electrically connects the second transistor T2 and the pixel electrode PE. The connection part 150 may be electrically connected to the second source electrode SE2 or the third capacitor electrode SC3 through contact holes formed in the second passivation layer 116, the first planarization layer 115, and the first passivation layer 114.

The connection part 150 may have a multilayer structure including a first connection layer 150a and a second connection layer 150b. The first connection layer 150a is disposed on the second passivation layer 116, and the second connection layer 150b is disposed to cover the first connection layer 150a. The second connection layer 150b may be disposed to surround both a top surface and a side surface of the first connection layer 150a. The second connection layer 150b may be made of a material more resistant to corrosion than a material of the first connection layer 150a. Therefore, it is possible to minimize short-circuit defects caused by migration between lines adjacent to the first connection layer 150a during the process of manufacturing the display device 100. For example, the first connection layer 150a may be made of an electrically conductive material such as copper (Cu) and chromium (Cr). The second connection layer 150b may be made of molybdenum (Mo) and molybdenum titanium (MoTi). However, the present disclosure is not limited thereto.

The first line 121 and the second line 122 are disposed on the second passivation layer 116. The first line 121 and the second line 122 transmit the low-potential power voltage to the light-emitting element 130. Therefore, the first line 121 and the second line 122 may each be referred to as a low-potential power line. However, the first line 121 and the second line 122 may transmit the high-potential power voltage. In this case, the pixel electrode PE may transmit the low-potential power voltage. The plurality of first lines 121 and the plurality of second lines 122 may be disposed on each of the plurality of sub-pixels SP and separated from one another while extending in the column direction. For example, the pair of first lines 121 and the pair of second lines 122 may be disposed on each of the first sub-pixel SP1, the second sub-pixel SP2, and the third sub-pixel SP3 and spaced apart from one another at predetermined intervals.

The first line 121 and the second line 122 may serve as assembly lines or assembly electrodes for self-assembly of the light-emitting element 130. For example, during the process of manufacturing the display device 100, the first line 121 and the second line 122 may form an electric field to self-assemble the light-emitting element 130.

The first line 121 and the second line 122 may respectively include conductive layers 121a and 122a and clad layers 121b and 122b. In some aspects, the first line 121 includes a first conductive layer 121a and a first clad layer 121b. The second line 122 includes a second conductive layer 122a and a second clad layer 122b.

The conductive layers 121a and 122a of the first and second lines 121 and 122 are disposed on the second passivation layer 116. The clad layers 121b and 122b are disposed on the conductive layers 121a and 122a and cover both the top surfaces and the side surfaces of the conductive layers 121a and 122a. For example, the conductive layers 121a and 122a may each be made of an electrically conductive material such as copper (Cu) and chromium (Cr). Further, the clad layers 121b and 122b may each be made of a material more resistant to corrosion than materials of the conductive layers 121a and 122a. For example, the clad layers 121b and 122b may each be made of molybdenum (Mo), molybdenum titanium (MoTi), and the like. However, the present disclosure is not limited thereto.

The clad layers 121b and 122b of the first and second lines 121 and 122 may be disposed to protrude toward the area in which the plurality of light-emitting elements 130 are disposed. In some cases, the clad layers 121b and 122b are configured to overlap the area including the plurality of light-emitting elements 130 and allow the first line 121 and the second line 122 to serve as the electrodes for self-assembly of the light-emitting element 130.

The third passivation layer 117 is disposed on the connection part 150, the first line 121, and the second line 122. The third passivation layer 117 may be an insulation layer for protecting components disposed below the third passivation layer 117. The third passivation layer 117 may be configured as a single layer or multilayer made of silicon oxide (SiOx) or silicon nitride (SiNx). However, the present disclosure is not limited thereto.

The plurality of light-emitting elements 130 are disposed on the third passivation layer 117. One or more light-emitting elements 130 are disposed on one sub-pixel SP. The light-emitting element 130 emits light by receiving an electric current. The light-emitting elements 130 may include the light-emitting elements 130 configured to emit red light, green light, blue light, and the like. The light-emitting elements 130 may implement light with various colors including white by using a combination of red light, green light, blue light, and the like. In addition, light beams with various colors may be implemented by using the light-emitting element 130, which emits light with a particular color, and a photoconversion member may converts the light from the light-emitting element 130 into light with a different color. The light-emitting element 130 may be electrically connected between the second transistor T2, the first line 121, and the second line 122. The storage capacitor Cst and the transistors T1. T2. T3 for driving the light-emitting element 130 may be referred to as a driving circuit and the light-emitting element 130 emit light by receiving the drive current from the driving circuit. Here, the driving circuit may be configured to a driving chip.

In this case, the plurality of light-emitting elements 130 disposed on one sub-pixel SP may be connected in parallel. That is, one electrode of each of the plurality of light-emitting elements 130 may be connected to the same source electrode of the second transistor T2, and another electrode may be connected to the same lines 121 and 122.

In some aspects, the light-emitting elements 130 respectively disposed on the plurality of sub-pixels SP may have different structures. For example, the light-emitting elements 130 may include a first light-emitting element 130a, a second light-emitting element 130b, and a third light-emitting element 130c. The first light-emitting element 130a may be disposed on the first sub-pixel SP1 of the plurality of sub-pixels SP. The second light-emitting element 130b may be disposed on the second sub-pixel SP2 of the plurality of sub-pixels SP. The third light-emitting element 130c may be disposed on the third sub-pixel SP3 of the plurality of sub-pixels SP. However, the type of light-emitting element 130 is exemplary. One of the first light-emitting element 130a, the second light-emitting element 130b, and the third light-emitting element 130c may be used as the light-emitting element 130. Alternatively, another type of light-emitting element 130 may be used. However, the present disclosure is not limited thereto. In addition, for convenience of description, FIG. 2A illustrates that two light-emitting elements 130 are disposed on each of the plurality of sub-pixels SP. The number of light-emitting elements 130 respectively disposed on the plurality of sub-pixels SP. However, the present disclosure is not limited thereto.

With reference to FIG. 2A, the light-emitting elements 130 respectively disposed on the plurality of sub-pixels SP may have different sizes. For example, the first light-emitting element 130a, which is disposed on the first sub-pixel SP1 among the plurality of sub-pixels SP, may be larger than the second light-emitting element 130b disposed on the second sub-pixel SP2 and the third light-emitting element 130c disposed on the third sub-pixel SP3. The second light-emitting element 130b disposed on the second sub-pixel SP2 may be larger than the third light-emitting element 130c disposed on the third sub-pixel SP3. However, the present disclosure is not limited thereto.

The plurality of light-emitting elements 130 each includes a first semiconductor layer 131, a light-emitting layer 132, a second semiconductor layer 133, a first electrode 134, a second electrode 135, and a sealing layer 136.

The first semiconductor layer 131 is disposed on the third passivation layer 117, and the second semiconductor layer 133 is disposed on the first semiconductor layer 131. The first semiconductor layer 131 and the second semiconductor layer 133 may each be formed by doping a particular material with n-type and p-type impurities. For example, the first semiconductor layer 131 and the second semiconductor layer 133 may each be a layer formed by doping a material, such as gallium nitride (GaN), indium aluminum phosphide (InAlP), or gallium arsenic (GaAs) with p-type or n-type impurities. Non-limiting examples of the p-type impurity include magnesium (Mg), zinc (Zn), beryllium (Be), or the like. Non-limiting examples of the n-type impurity include silicon (Si), germanium (Ge), tin (Sn), or the like. However, the present disclosure is not limited thereto.

A part of the first semiconductor layer 131 may be disposed to protrude to the outside of the second semiconductor layer 133. A top surface of the first semiconductor layer 131 may include a portion overlapping a bottom surface of the second semiconductor layer 133 and a portion disposed outside a bottom surface of the second semiconductor layer 133. However, the first semiconductor layer 131 and the second semiconductor layer 133 may be modified to have various sizes and shapes. However, the present disclosure is not limited thereto.

The light-emitting layer 132 is disposed between the first semiconductor layer 131 and the second semiconductor layer 133. The light-emitting layer 132 may emit light by receiving positive holes and electrons from the first semiconductor layer 131 and the second semiconductor layer 133. The light-emitting layer 132 may be configured as a single layer or a multi-quantum well (MQW) structure. Non-limiting examples of materials of the light-emitting layer 132 include indium gallium nitride (InGaN), gallium nitride (GaN), or the like. However, the present disclosure is not limited thereto.

The first electrode 134 is disposed to surround the bottom surface and the side surface of the first semiconductor layer 131. The first electrode 134 electrically connects the first light-emitting element 130 and the lines 121 and 122. The first electrode 134 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 135 is disposed on the top surface of the second semiconductor layer 133. The second electrode 135 electrically connects the pixel electrode PE and the second semiconductor layer 133 that will be described below. The second electrode 135 may be made of an electrically conductive material, e.g., a transparent conductive material such as indium tin oxide (ITO) or indium zinc oxide (IZO). However, the present disclosure is not limited thereto.

The sealing layer 136 is disposed to at least partially surround the first semiconductor layer 131, the light-emitting layer 132, the second semiconductor layer 133, the first electrode 134, and the second electrode 135. The sealing layer 136 may be made of an insulating material and protects the first semiconductor layer 131, the light-emitting layer 132, and the second semiconductor layer 133. The sealing layer 136 may be disposed to cover the light-emitting layer 132, a part of a side surface of the first semiconductor layer 131 adjacent to the light-emitting layer 132, and a part of a side surface of the second semiconductor layer 133 adjacent to the light-emitting layer 132. The first electrode 134 and the second electrode 135 may be exposed by the sealing layer 136. Therefore, the pixel electrode PE and the second electrode 135, which are formed subsequently, may be electrically connected.

The metal layer 140 is disposed on the lines 121 and 122. Specifically, the metal layer 140 may be provided between the third passivation layer 117 and the light-emitting element 130 and be in contact with a part of the side surface of the light-emitting element 130 and the lines 121 and 122. The metal layer 140 is disposed on the first line 121 and the second line 122 to overlap the first line 121 and the second line 122. In this case, the metal layer 140 is connected to the first line 121 and the second line 122 through a contact hole of the third passivation layer 117 disposed outside the light-emitting element 130.

The metal layer 140 includes a first part 141 and a second part 142.

The first part 141 is disposed between the light-emitting element 130 and the third passivation layer 117. Therefore, the first part 141 may be in contact with a bottom surface of the light-emitting element 130. In one aspect, the first part 141 may be in contact with the first electrode 134 of the light-emitting element 130. In this case, the first part 141 of the metal layer 140 may serve as a bonding layer for fixing or bonding the light-emitting element 130 to the third passivation layer 117.

The second part 142 may be in contact with a part of the side surface of the light-emitting element 130 extending from the bottom surface of the light-emitting element 130. That is, the second part 142 may extend from the first part 141 and be in contact with a part of the side surface adjacent to the bottom surface of the light-emitting element 130. Therefore, the second part 142 may be in contact with a part of the side surface of the sealing layer 136 of the light-emitting element 130. In addition, the second part 142 may be connected to the first line 121 and the second line 122 through the contact hole of the third passivation layer 117.

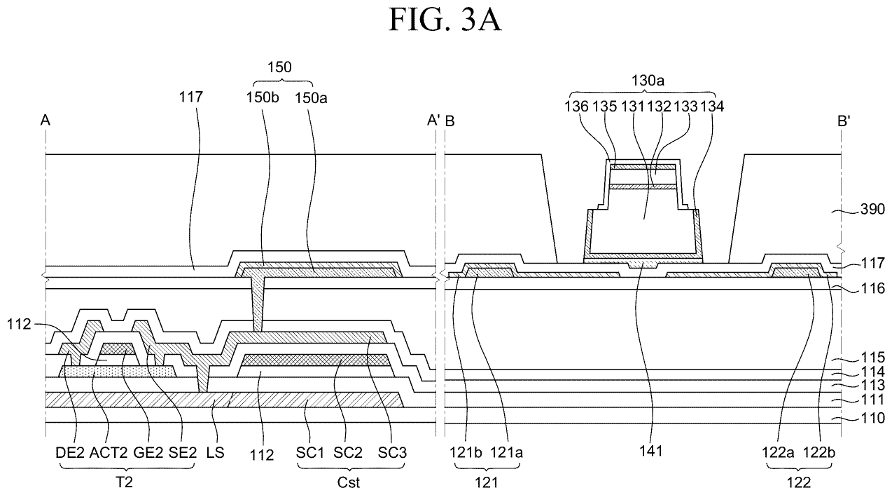

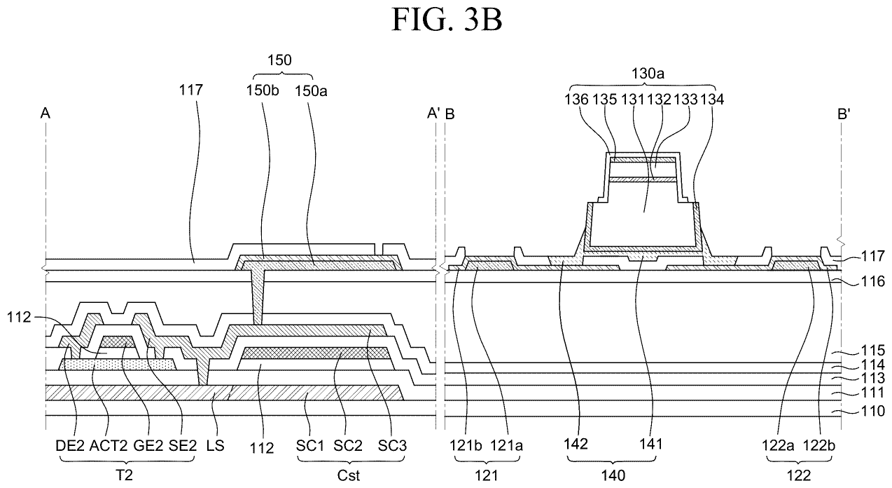

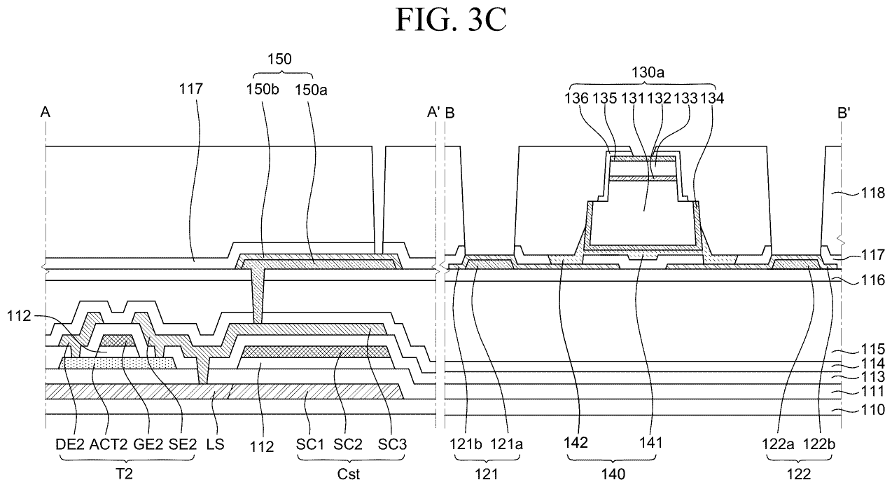

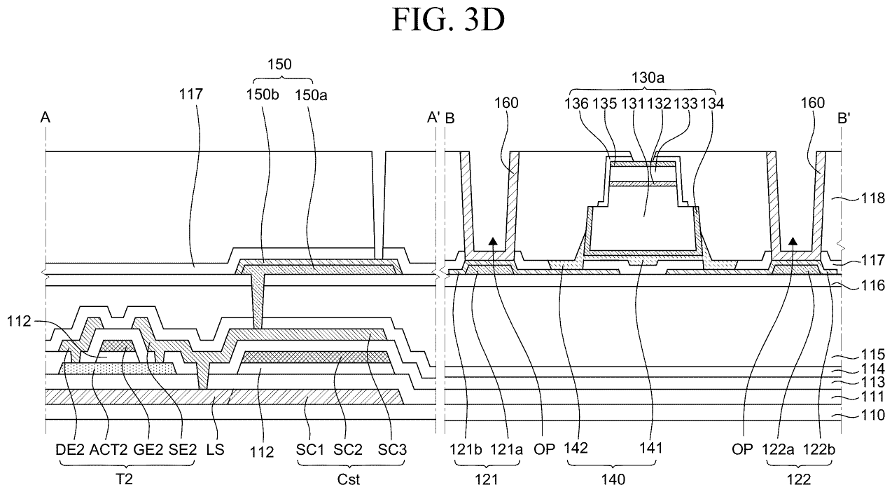

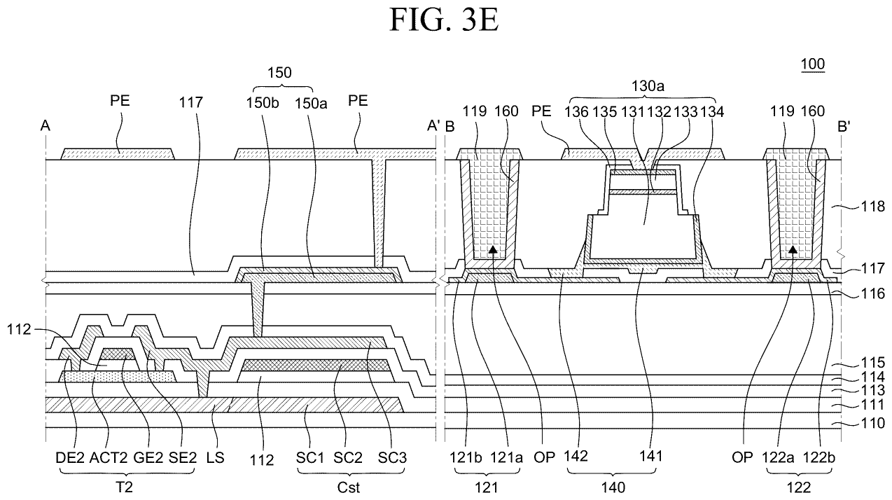

The metal layer 140 may be formed by a metal inkjet process. For example, the metal layer 140 may be made by curing liquid metal or metal paste. Non-limiting examples of a metal paste include a silver paste (e.g., Ag paste), a gold paste (e.g., Au paste), a metal alloy paste, and so forth. A process of manufacturing the metal layer 140 will be described below in detail with reference to FIGS. 3A to 3E.

Next, the second planarization layer 118 is disposed on the light-emitting element 130. The second planarization layer 118 may planarize the upper portion of the substrate 110 on which the light-emitting element 130 is disposed. The second planarization layer 118, together with the metal layer 140, may fix the light-emitting element 130 onto the substrate 110. The second planarization layer 118 may be configured as a single layer or multilayer and made of an acrylic-based organic material, for example. However, the present disclosure is not limited thereto.

Openings OP are disposed in the second planarization layer 118 and the third passivation layer 117. The opening OP may expose top surfaces of the first line 121 and the second line 122. In addition, a side surface of the opening OP may have an inclined shape. For example, with reference to FIG. 2B, the opening OP may have an inversely trapezoidal shape. However, the present disclosure is not limited thereto. In addition, with reference to FIG. 2B, the opening OP may overlap the conductive layers 121a and 122a.

The reflective layer 160 is disposed on the side surface of the opening OP. The reflective layer 160 may reflect light beams, which propagate toward the side surface of the light-emitting element 130 among the light beams emitted from the light-emitting element 130, thereby increasing the amount of light extracted. Therefore, the reflective layer 160 may be made of a metallic material with high reflectance.

The reflective layer 160 may be disposed on the side surface and the bottom surface of the opening OP. Therefore, the reflective layer 160 may be disposed to be in contact with the side surface of the second planarization layer 118, which is the side surface of the opening OP, the top surface of the first line 121 exposed by the opening OP, and the top surface of the second line 122 exposed by the opening OP.

With reference to FIG. 2B, the reflective layer 160 may be disposed on both the side surfaces of the openings OP. However, the present disclosure is not limited thereto. The reflective layer 160 may be disposed on the side surface of the opening OP adjacent to the light-emitting element 130. As described below, because a filling layer 119, which fills the opening OP, is made of a black material, the reflective layer 160 may be disposed on the side surface of the opening OP adjacent to the light-emitting element 130.

The opening OP on which the reflective layer 160 is disposed is filled with the filling layer 119. The filling layer 119 may fill the opening OP to mitigate a level difference caused by the opening OP.

The filling layer 119 may be made of a black material. For example, the filling layer 119 may be made of a black material to inhibit external light from being reflected by the reflective layer 160 disposed below the filling layer 119.

The pixel electrode PE is disposed on the second planarization layer 118.

The pixel electrode PE may electrically connect the plurality of light-emitting elements 130 and the connection part 150. The pixel electrode PE is electrically connected to the plurality of light-emitting elements 130. Specifically, the pixel electrode PE may be electrically connected to the light-emitting element 130, the connection part 150, and the driving circuit through contact holes formed in the second planarization layer 118. Therefore, the second electrode 135 of the light-emitting element 130, the connection part 150, the second source electrode SE2 of the driving circuit may be electrically connected through the pixel electrode PE. The pixel electrode PE may be made of an electrically conductive material, e.g., a transparent conductive material such as indium tin oxide (ITO) or indium zinc oxide (IZO). However, the present disclosure is not limited thereto.

Hereinafter, a process of manufacturing the display device 100 according to the aspect of the present disclosure will be described in more detail with reference to FIGS. 3A to 3E.

FIGS. 3A to 3E are views for explaining a process of manufacturing the display device according to the aspect of the present disclosure.

First, with reference to FIG. 3A, a temporary organic layer 390 is disposed on the third passivation layer 117. The temporary organic layer 390 may provide a pocket for self-assembling the light-emitting element 130.

Next, when the self-assembly is performed when the temporary organic layer 390 is disposed over the third passivation layer 117, the light-emitting element 130 is also disposed on the third passivation layer 117. In this case, a small space may be present between the light-emitting element 130 and the third passivation layer 117. The bottom surface of the light-emitting element 130 and the top surface of the third passivation layer 117 may inevitably have curved portions as part of the assembly process because perfect flat surfaces cannot be guaranteed at this scale. Therefore, the light-emitting element 130 and the third passivation layer 117 may partially be in contact with each other and may have gaps between their surfaces.

Next, the metal inkjet process is performed during the self-assembly of the light-emitting element 130. In one aspect, liquid metal or metal paste is injected between the light-emitting element 130 and the third passivation layer 117 by an inkjet process while the light-emitting element 130 is disposed on the third passivation layer 117, the liquid metal or silver paste may permeate between the light-emitting element 130 and the third passivation layer 117. Thereafter, when a curing process is performed, the first part 141 of the metal layer 140 is formed between the light-emitting element 130 and the third passivation layer 117. Therefore, the first part 141 of the metal layer 140 may be cured at a portion below the light-emitting element 130 and fixes the light-emitting element 130.

Meanwhile, FIG. 3A illustrates that only the first part 141 of the metal layer 140 is formed. However, the present disclosure is not limited thereto, the second part 142 of the metal layer 140 may also be formed. In one aspect, the liquid metal or silver paste is applied onto the side surface of the light-emitting element 130 during the metal inkjet process and the second part 142 of the metal layer 140 may be formed together with the first part 141 during the curing process.

Next, with reference to FIG. 3B, the temporary organic layer 390 is removed. Because the temporary organic layer 390 is a layer temporarily used for the self-assembly process, the temporary organic layer 390 is removed before a subsequent process.

The contact hole and the opening OP are formed in the third passivation layer 117. The third passivation layer 117 may have the contact holes that expose the connection part 150, the first line 121, and the second line 122, and the openings that expose the first line 121 and the second line 122.

In some aspects, the metal inkjet process may then performed. For example, the second part 142 of the metal layer 140 may be formed. The second part 142 of the metal layer 140 connects the first line 121, the second line 122, the light-emitting element 130, and the first part 141 of the metal layer 140 through the contact holes of the third passivation layer 117. Similar to the first part 141 of the metal layer 140, the second part 142 of the metal layer 140 is formed by the metal inkjet process. Therefore, there is no interface between the first part 141 and the second part 142, and the first part 141 and the second part 142 may be integrated. However, the present disclosure is not limited thereto.

FIG. 3B illustrates that the second part 142 of the metal layer 140 and the first part 141 of the metal layer 140 are formed by the separate processes. However, the present disclosure is not limited thereto. The first part 141 and the second part 142 of the metal layer 140 may be simultaneously formed by the process described with reference to FIG. 3A.

With reference to FIG. 3C, the second planarization layer 118 is formed. The second planarization layer 118 may planarize the light-emitting element 130, the first line 121, and the second line 122. Meanwhile, the opening OP of the second planarization layer 118 may be formed through a patterning process such as an etching process.

Next, with reference to FIG. 3D, the reflective layer 160 is formed on the side surface of the opening OP. The reflective layer 160 may be formed by a deposition process. However, the present disclosure is not limited thereto. Similar to the metal layer 140, the reflective layer 160 may also be formed by the metal inkjet process.

Next, with reference to FIG. 3E, the filling layer 119, which fills the opening OP, is formed, and the pixel electrode PE is formed.

In case that the display device is manufactured by the self-assembly method, the temporary organic layer is used to provide a space for assembling the light-emitting element. After the light-emitting element is assembled, a temporary planarization layer for planarizing the upper portion of the light-emitting element is disposed. Thereafter, the temporary organic layer and the temporary planarization layer are removed to electrically connect the assembly line and the light-emitting element and electrically connect the light-emitting element and the transistor. In this case, the light-emitting element may not be properly fixed to the substrate. A part of the temporary planarization layer may permeate into a lower portion of the light-emitting element and fix the light-emitting element while forming the temporary planarization layer. However, because the constituent element for attaching the light-emitting element is a part of the temporary planarization layer, it is difficult to sufficiently attach the light-emitting element. In case that the light-emitting element is not sufficiently attached as described above, the light-emitting element may be inoperable or may be damaged easily. In addition, even when the light-emitting element is not inoperable, the arrangement position of the light-emitting element may be different than the intended design, which may cause the pixel electrode to be connected to the assembly line for supplying low-potential power (e.g., a defect).

Therefore, in the display device 100 according to the aspect of the present disclosure, it is possible to increase a bonding strength of the light-emitting element 130 by using the metal layer 140 that is disposed between the light-emitting element 130 and the third passivation layer 117. Because the metal layer 140 is formed by the metal inkjet process, the metal layer 140 in a liquid state is injected into the lower portion of the light-emitting element 130 and then cured. Therefore, the light-emitting element 130 may be fixed onto the third passivation layer 117 by a higher bonding strength. Therefore, the display device 100 according to the aspect of the present disclosure may prevent a problem with connection between the pixel electrode PE and the lines 121 and 122 caused by a loss of the light-emitting element 130 or the misalignment of the light-emitting element 130.

Meanwhile, the light-emitting layer of the light-emitting element emits light in all directions. In this case, the light emitted in a direction of the front surface of the display device is normally extracted to the outside of the display device. The light emitted toward the lower portion of the light-emitting element may be reflected by the assembly line and extracted in the direction of the front surface of the display device. However, the light emitted to a lateral portion of the light-emitting element may be trapped in the display device while being totally reflected within the display device. In this case, light that is totally reflected is not extracted in the direction of the high front surface of the display device, which may reduce the light extraction efficiency of the display device.

Therefore, in the display device 100 according to the aspect of the present disclosure, the reflective layer 160 may be disposed on the lateral portion of the light-emitting element 130 to improve luminous efficiency. The light emitted to the lateral portion of the light-emitting element 130 may be reflected by the reflective layer 160 disposed on the lateral portion of the light-emitting element 130 and propagate in the direction of the front surface of the display device 100. Therefore, the display device 100 according to the aspect of the present disclosure may improve efficiency in extracting light emitted from the light-emitting element 130.

In addition, the display device 100 according to the aspect of the present disclosure may reduce the reflection of external light by the reflective layer 160 disposed on the opening OP. In case that the reflective layer 160 is disposed to improve the light extraction efficiency, the external light may be reflected by the reflective layer 160 and visually recognized by the user. Therefore, in the display device 100 according to the aspect of the present disclosure, the filling layer 119 made of a black material may be disposed in the opening OP, to minimize the reflection of external light by the reflective layer 160.

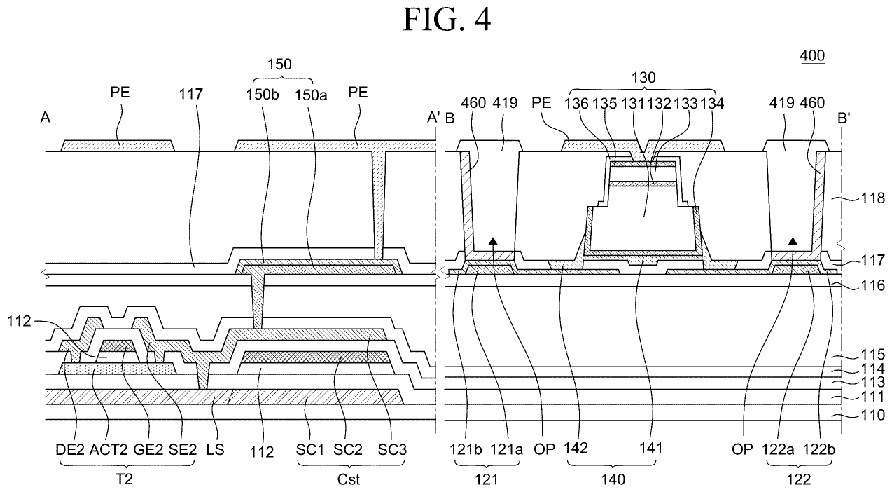

FIG. 4 is a cross-sectional view of a display device according to another aspect of the present disclosure. A display device 400 in FIG. 4 is similar in configuration to the display device 100 in FIGS. 1 to 3E, except for a filling layer 419 and a reflective layer 460. Therefore, repeated descriptions of the identical components will be omitted.

With reference to FIG. 4, the reflective layer 460 is disposed on the side surface of the opening OP. The reflective layer 460 may reflect light beams, which propagate toward the side surface of the light-emitting element 130 among the light beams emitted from the light-emitting element 130, thereby increasing the amount of light extracted forward. Therefore, the reflective layer 460 may be made of a metallic material with high reflectance.

The reflective layer 460 may be disposed on the side surface of the opening OP that faces the light-emitting element 130. The reflective layer 460 may be disposed on the side surface of the opening OP disposed to be relatively distant from the light-emitting element 130. Therefore, the reflective layer 460 may be disposed to be in contact with the side surface of the second planarization layer 118 facing the light-emitting element 130, e.g., the side surface of the opening OP and be in contact with the top surfaces of the lines 121 and 122 exposed by the opening OP.

The reflective layer 460 may be disposed at an angle for reflecting the light, which is emitted from the light-emitting element 130, in the direction of the front surface of the display device 400. For example, an angle defined between a portion of the reflective layer 460, which contacts the top surfaces of the lines 121 and 122, and a portion of the side surface of the opening OP, which contacts the side surface facing the light-emitting element 130, may be an obtuse angle.

With reference to FIG. 4, the opening OP on the reflective layer 460 is filled with the filling layer 419. The filling layer 419 may fill the opening OP to mitigate a level difference caused by the opening OP.

In some aspects, the filling layer 419 may be a transparent material. As described above, the reflective layer 460 may be disposed on the side surface of the opening OP that faces the light-emitting element 130. Therefore, the second planarization layer 118 and the filling layer 419 disposed between the light-emitting element 130 and the reflective layer 460 may be transparent so that the light emitted from the light-emitting element 130 is reflected by the reflective layer 460 and propagates in the direction of the front surface of the display device 400. Therefore, the filling layer 419 may be made of a transparent material among acrylic-based organic materials identical to a material of the second planarization layer 118.

In the display device 400 according to another aspect of the present disclosure, the bonding strength of the light-emitting element 130 is increased by using a metal layer 140 between the light-emitting element 130 and the third passivation layer 117. Therefore, the display device 400 according to another aspect of the present disclosure may prevent the electrical connection between the pixel electrode PE and the lines 121 and 122 caused by a loss of the light-emitting element 130 or the misalignment of the light-emitting element 130.

In addition, in the display device 400 according to another aspect of the present disclosure, the reflective layer 460 may be disposed on the lateral portion of the light-emitting element 130, thereby improving luminous efficiency. The light emitted to the lateral portion of the light-emitting element 130 may be reflected by the reflective layer 460 disposed on the lateral portion of the light-emitting element 130 and propagate in the direction of the front surface of the display device 400. In particular, an angle defined between a portion of the reflective layer 460, which contacts the top surfaces of the lines 121 and 122, and a portion of the side surface of the opening OP, which contacts the side surface facing the light-emitting element 130, may be an obtuse angle. Therefore, the light emitted from the light-emitting element 130 may be more efficiently reflected in the direction of the front surface of the display device 400. Therefore, the display device 400 according to another aspect of the present disclosure may improve efficiency in extracting light emitted from the light-emitting element 130.

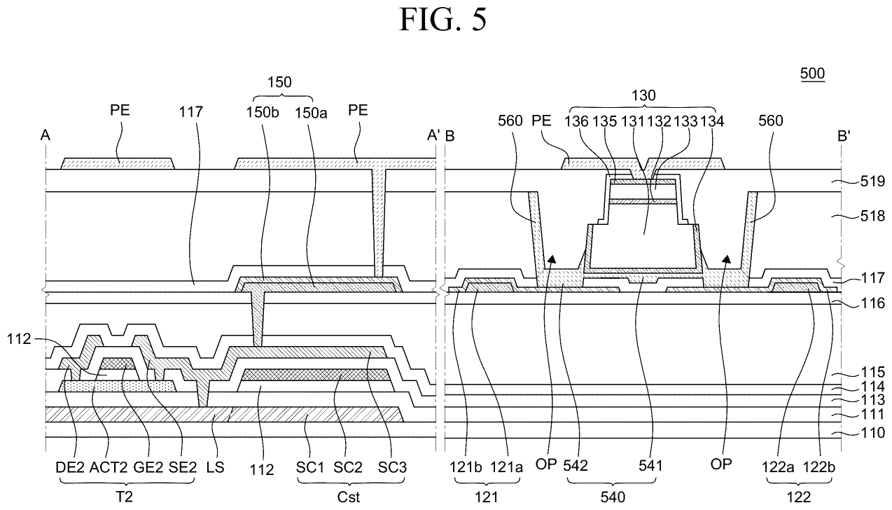

FIG. 5 is a cross-sectional view of a display device according to still another aspect of the present disclosure. A display device 500 in FIG. 5 is substantially identical in configuration to the display device 100 in FIGS. 1 to 3E, except for a second planarization layer 518, a third planarization layer 519, the metal layer 540, and a reflective layer 560. Therefore, repeated descriptions of the identical components will be omitted.

With reference to FIG. 5, the second planarization layer 518 is disposed to cover the first line 121 and the second line 122. The second planarization layer 518 may planarize an upper portion of the third passivation layer 117. The second planarization layer 518 may be configured as a single layer or multilayer and made of an acrylic-based organic material, for example. However, the present disclosure is not limited thereto.

The second planarization layer 518 may have the opening OP that surrounds the light-emitting element 130. Therefore, the second planarization layer 518 may be separated from the light-emitting element 130. The opening OP may also be formed in the third passivation layer 117, thereby exposing the top surface of the first clad layer 121b of the first line 121 and the top surface of the second clad layer 122b of the second line 122. In addition, a side surface of the opening OP may have an inclined shape or tapered shape. For example, with reference to FIG. 2B, the opening OP may have a shape similar to an inversely trapezoidal shape. However, the present disclosure is not limited thereto.

The metal layer 540 is disposed on the lines 121 and 122. Specifically, the metal layer 540 may be provided between the third passivation layer 117 and the light-emitting element 130 and be in contact with a part of the side surface of the light-emitting element 130 and the lines 121 and 122. The metal layer 540 is disposed on the first line 121 and the second line 122 to overlap the first line 121 and the second line 122. In this case, the metal layer 540) is connected to the first line 121 and the second line 122 through a contact hole of the third passivation layer 117 disposed outside the light-emitting element 130.

The metal layer 540 includes a first part 541 and a second part 542.

The first part 541 is disposed between the light-emitting element 130 and the third passivation layer 117. Therefore, the first part 541 may be in contact with the bottom surface of the light-emitting element 130, specifically be in contact with the first electrode 134 of the light-emitting element 130. In this case, the first part 541 of the metal layer 540 may serve as a bonding layer for fixing or bonding the light-emitting element 130 to the third passivation layer 117.

The second part 542 may be in contact with a part of the side surface of the light-emitting element 130 extending from the bottom surface of the light-emitting element 130. That is, the second part 542 may extend from the first part 541 and be in contact with a part of the side surface adjacent to the bottom surface of the light-emitting element 130. Therefore, the second part 542 may be in contact with a part of the side surface of the sealing layer 136 of the light-emitting element 130. In addition, the second part 542 may be connected to the first line 121 and the second line 122 through the contact hole of the third passivation layer 117.

The metal layer 540 may be formed by a metal inkjet process. For example, the metal layer 540 may be a layer made by curing a liquid metal or silver paste (Ag paste).

The reflective layer 560 is disposed on the side surface of the opening OP. The reflective layer 560 may reflect light beams, which propagate toward the side surface of the light-emitting element 130 among the light beams emitted from the light-emitting element 130, thereby increasing the amount of light extracted forward. Therefore, the reflective layer 560 may be made of a metallic material with high reflectance.

The reflective layer 560 may be disposed on the side surface of the opening OP. Therefore, the reflective layer 560 may be disposed to be in contact with the side surface of the second planarization layer 518, i.e., the side surface of the opening OP.

The reflective layer 560 may be made of the same material as the metal layer 540. That is, the reflective layer 560 may be made of a material that may be formed by a metal inkjet process. For example, the metal layer 540 may be a layer made by curing a liquid metal or silver paste (Ag paste).

The reflective layer 560 may be formed by the same process as the metal layer 540. For example, the reflective layer 560 and the second part 542 of the metal layer 540 may be simultaneously formed by the same process. However, the present disclosure is not limited thereto. The metal inkjet process for forming the reflective layer 560 may be performed after the metal inkjet process for forming the metal layer 540.

Both the process of forming the reflective layer 560 and the process of forming the metal layer 540 are the metal inkjet processes, such that the reflective layer 560 and the metal layer 540 may be connected to each other. Therefore, as illustrated in FIG. 5, no interface may be present between the reflective layer 560 and the metal layer 540, and the reflective layer 560 and the metal layer 540 may be integrated. However, the present disclosure is not limited thereto. The reflective layer 560 and the metal layer 540 may be separated from each other. In addition, the reflective layer 560 and the metal layer 540 may be made of different materials and made by different processes.

The third planarization layer 519 is disposed to fill the opening OP on which the reflective layer 560 and the light-emitting element 130 are disposed, and the third planarization layer 519 planarizes the upper portion. The third planarization layer 519 may fill the opening OP and be disposed on the second planarization layer 518. Therefore, the third planarization layer 519 may mitigate a level difference caused by the opening OP. The third planarization layer 519 may include a contact hole exposing the second electrode 135 of the light-emitting element 130. The pixel electrode PE may be disposed on the third planarization layer 519 and electrically connected to the light-emitting element 130 through the contact hole formed in the third planarization layer 519. The third planarization layer 519 may be configured as a single layer or multilayer and made of an acrylic-based organic material, for example. However, the present disclosure is not limited thereto.

In the display device 500 according to still another aspect of the present disclosure, it is possible to increase a bonding strength of the light-emitting element 130 by using a metal layer 540 disposed between the light-emitting element 130 and the third passivation layer 117. Therefore, the display device 500 according to still another aspect of the present disclosure may prevent an electrical connection between the pixel electrode PE and the lines 121 and 122 caused by a loss of the light-emitting element 130 or the misalignment of the light-emitting element 130).

In addition, in the display device 500 according to still another aspect of the present disclosure, the reflective layer 560 may be disposed on the lateral portion of the light-emitting element 130, thereby improving luminous efficiency. The light emitted to the lateral portion of the light-emitting element 130 may be reflected by the reflective layer 560 disposed on the lateral portion of the light-emitting element 130 and propagate in the direction of the front surface of the display device 500. In particular, the opening OP of the second planarization layer 518 exposes the first clad layer 121b of the first line 121 adjacent the light-emitting element 130 and the second clad layer 122b of the second line 122, such that the reflective layer 560 is connected to the second part 542 of the metal layer 540 disposed on the first clad layer 121b of the first line 121 and the second clad layer 122b of the second line 122. Therefore, a distance between the light-emitting element 130 and the reflective layer 560 is reduced, such that a larger amount of light emitted from the light-emitting element 130 may be reflected by the reflective layer 560. Therefore, the display device 500 according to still another aspect of the present disclosure may improve efficiency in extracting light emitted from the light-emitting element 130.

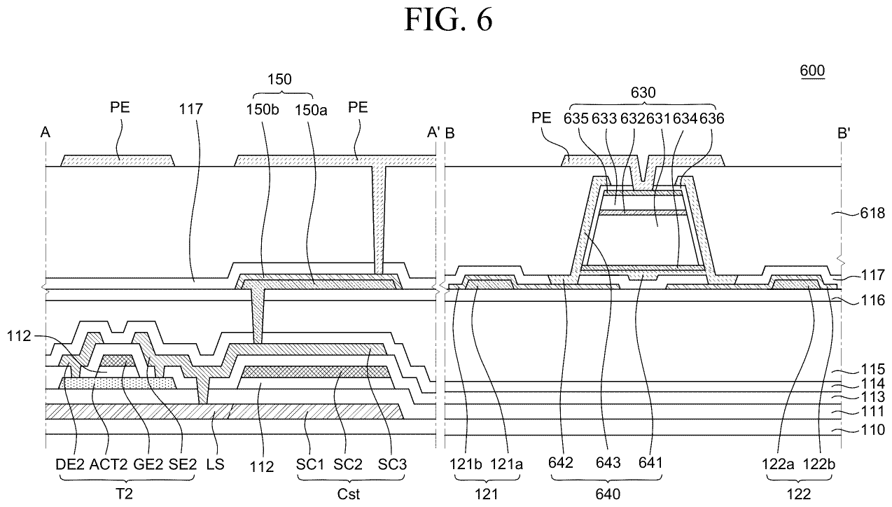

FIG. 6 is a cross-sectional view of a display device according to yet another aspect of the present disclosure. A display device 600 in FIG. 6 is substantially identical in configuration to the display device 100 in FIGS. 1 to 3E, except for a light-emitting element 630, a second planarization layer 618, and a metal layer 640. Therefore, repeated descriptions of the identical components will be omitted.

The plurality of light-emitting elements 630 is disposed on the third passivation layer 117. With reference to FIG. 6, the plurality of light-emitting elements 630 each includes a first semiconductor layer 631, a light-emitting layer 632, a second semiconductor layer 633, a first electrode 634, a second electrode 635, and a sealing layer 636.

The first semiconductor layer 631 is disposed on the third passivation layer 117, and the second semiconductor layer 633 is disposed on the first semiconductor layer 631. The first semiconductor layer 631 and the second semiconductor layer 633 may each be a layer formed by doping a particular material with n-type and p-type impurities. For example, the first semiconductor layer 631 and the second semiconductor layer 633 may each be a layer formed by doping a material, such as gallium nitride (GaN), indium aluminum phosphide (InAlP), or gallium arsenic (GaAs) with p-type or n-type impurities. Further, the p-type impurity may be magnesium (Mg), zinc (Zn), beryllium (Be), or the like. The n-type impurity may be silicon (Si), germanium (Ge), tin (Sn), or the like. However, the present disclosure is not limited thereto.

The light-emitting layer 632 is disposed between the first semiconductor layer 631 and the second semiconductor layer 633. The light-emitting layer 632 may emit light by receiving positive holes and electrons from the first semiconductor layer 631 and the second semiconductor layer 633. The light-emitting layer 632 may be configured as a single layer or a multi-quantum well (MQW) structure. For example, the light-emitting layer 632 may be made of indium gallium nitride (InGaN), gallium nitride (GaN), or the like. However, the present disclosure is not limited thereto.

The first electrode 634 is disposed on a bottom surface of the first semiconductor layer 631. The first electrode 634 electrically connects the light-emitting element 630 and the lines 121 and 122. The first electrode 634 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 635 is disposed on the top surface of the second semiconductor layer 633. The second electrode 635 electrically connects the pixel electrode PE and the second semiconductor layer 633 that will be described below. The second electrode 635 may be an electrically conductive material, e.g., a transparent conductive material such as indium tin oxide (ITO) or indium zinc oxide (IZO). However, the present disclosure is not limited thereto.

The sealing layer 636 is disposed to at least partially surround the first semiconductor layer 631, the light-emitting layer 632, the second semiconductor layer 633, and the second electrode 635. The sealing layer 636 may be made of an insulating material and protect the first semiconductor layer 631, the light-emitting layer 632, and the second semiconductor layer 633. The sealing layer 636 may be disposed to cover side surfaces of the first semiconductor layer 631, the light-emitting layer 632, and the second semiconductor layer 633. The first electrode 634 and the second electrode 635 may be exposed to the sealing layer 636. Therefore, the pixel electrode PE and the second electrode 635, which are formed subsequently, may be electrically connected.

A cross-section of the light-emitting element 630 may have a decreasing width in a direction from the bottom surface to the top surface. For example, as illustrated in FIG. 6, a cross-section of the light-emitting element 630 may have a trapezoidal shape. That is, in a cross-sectional view, the width of the cross-section may increase in the order of the second electrode 635, the second semiconductor layer 633, the light-emitting layer 632, the first semiconductor layer 631, and the first electrode 634.

The metal layer 640 is disposed on the lines 121 and 122. Specifically, the metal layer 640 may be provided between the third passivation layer 117 and the light-emitting element 630 and be in contact with the side surface of the light-emitting element 630 and the lines 121 and 122. The metal layer 640 is disposed on the first line 121 and the second line 122 to overlap the first line 121 and the second line 122. In this case, the metal layer 640 is connected to the first clad layer 121b of the first line 121 and the second clad layer 122b of the second line 122 through a contact hole of the third passivation layer 117 disposed outside the light-emitting element 630.

The metal layer 640 includes a first part 641, a second part 642, and a third part 643.

The first part 641 is disposed between the light-emitting element 630 and the third passivation layer 117. Therefore, the first part 641 may be in contact with the bottom surface of the light-emitting element 630, specifically be in contact with the first electrode 634 of the light-emitting element 630. In this case, the first part 641 of the metal layer 640 may serve as a bonding layer for fixing or bonding the light-emitting element 630 to the third passivation layer 117.

The second part 642 may connect the first part 641, the first line 121, and the second line 122. The second part 642 may be connected to the first clad layer 121b of the first line 121 and the second clad layer 122b of the second line 122 through the contact hole of the third passivation layer 117.

The third part 643 may contact the entire side surface of the light-emitting element 630. The third part 643 may be disposed to be in contact with the sealing layer 636 of the light-emitting element 630. In addition, as illustrated in FIG. 6, the third part 643 may contact with a part of the top surface of the light-emitting element 630.

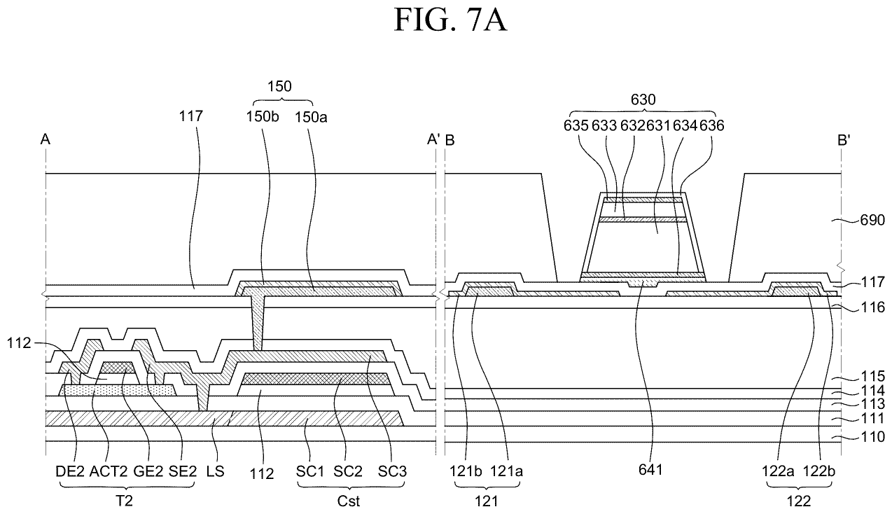

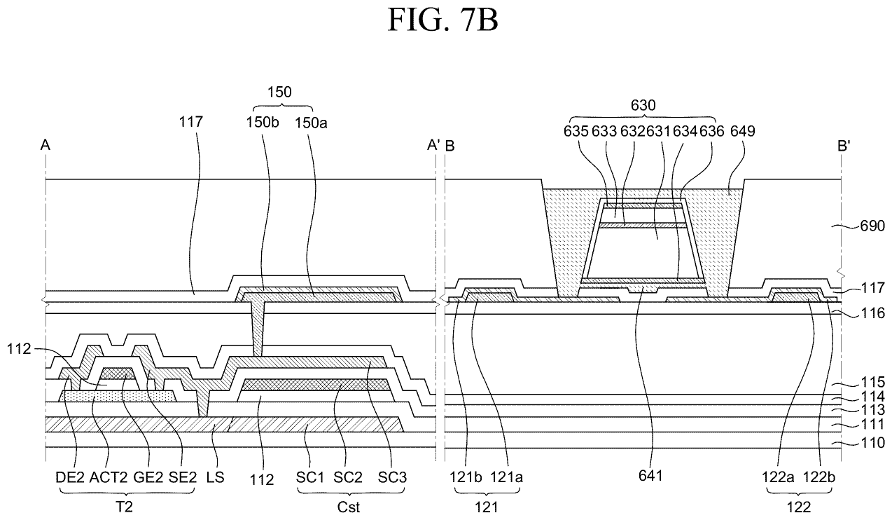

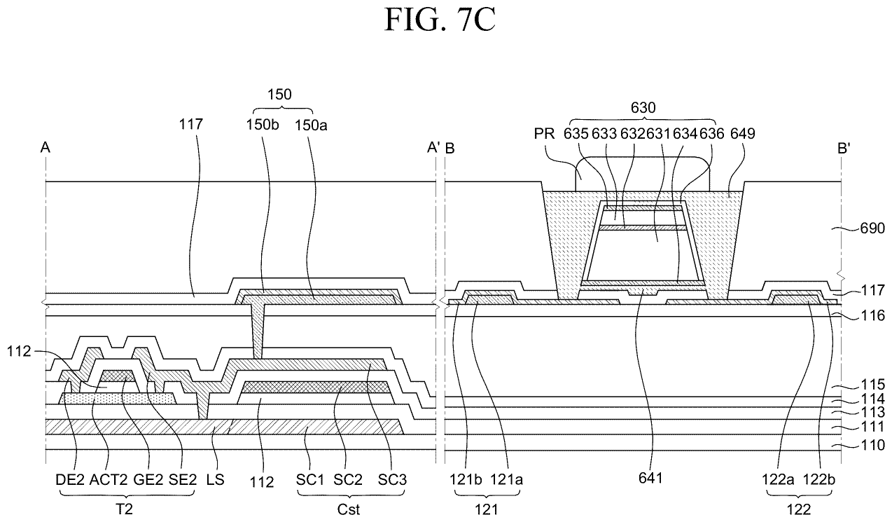

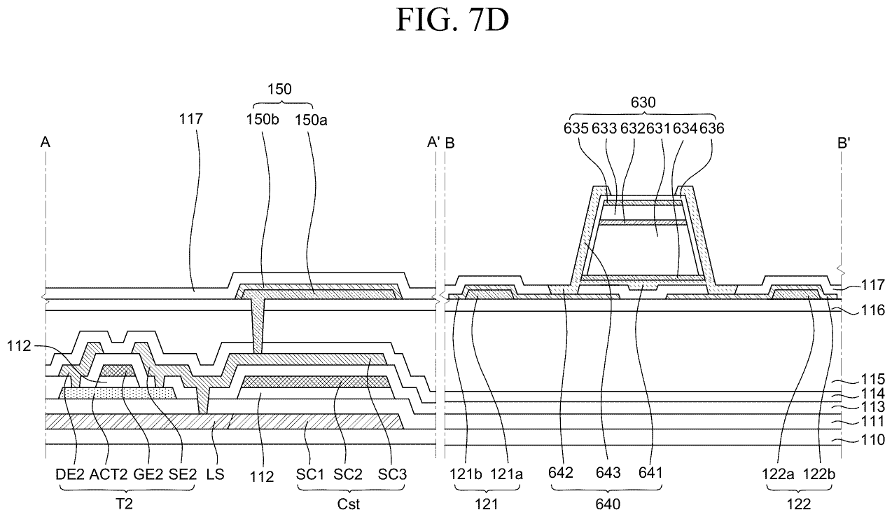

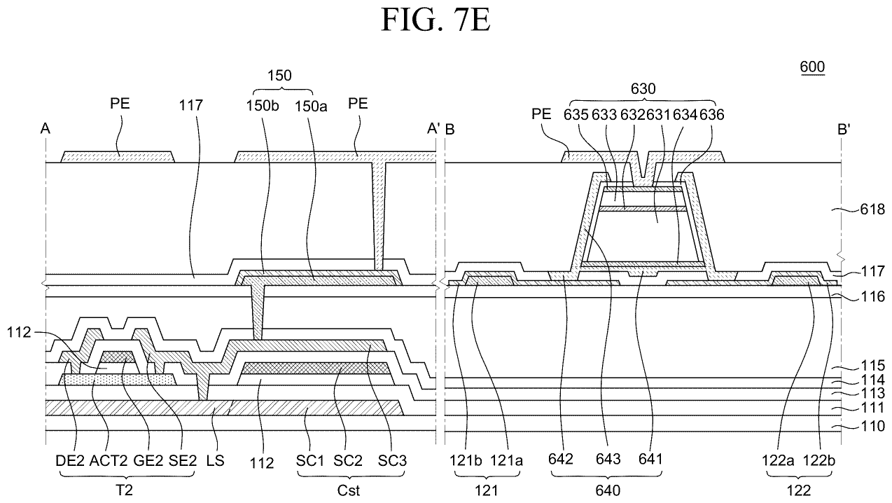

The metal layer 640 may be formed by a metal inkjet process. For example, the metal layer 640 may be a layer made by curing a liquid metal or silver paste (Ag paste). A process of manufacturing the metal layer 640 will be described below in detail with reference to FIGS. 7A to 7E.

Next, the second planarization layer 618 is disposed on the light-emitting element 630. The second planarization layer 618 may planarize the upper portion of the substrate 110 on which the first line 121, the second line 122, and the light-emitting element 630 are disposed. The second planarization layer 618, together with the metal layer 640, may attach the light-emitting element 630 onto the substrate 110. Therefore, the second planarization layer 618 may be in contact with the metal layer 640 disposed on the side surface of the light-emitting element 630. The second planarization layer 618 may be configured as a single layer or multilayer and made of an acrylic-based organic material, for example. However, the present disclosure is not limited thereto.

Hereinafter, a process of manufacturing the display device 600 according to yet another aspect of the present disclosure will be described in more detail with reference to FIGS. 7A to 7E.

FIGS. 7A to 7E are views for explaining a process of manufacturing the display device according to yet another aspect of the present disclosure.

First, with reference to FIG. 7A, a temporary organic layer 690 is disposed on the third passivation layer 117. The temporary organic layer 690 may space for self-assembling the light-emitting element 630.

Next, when the self-assembly is performed when the temporary organic layer 690 is disposed on the third passivation layer 117, the light-emitting element 630 is placed on the third passivation layer 117. In this case, a small space may be present between the light-emitting element 630 and the third passivation layer 117. The bottom surface of the light-emitting element 630 and the top surface of the third passivation layer 117 may inevitably have non-linear portions without having perfectly flat surfaces. Therefore, the light-emitting element 630 may partially contact the third passivation layer 117.

Next, with reference to FIG. 7B, the opening may be formed in the third passivation layer 117, thereby exposing a part of the first clad layer 121b of the first line 121 and a part of the second clad layer 122b of the second line 122.

Next, the metal inkjet process is performed. That is, a temporary metal layer 649 is formed between the light-emitting element 630 and the temporary organic layer 690 while the light-emitting element 630 is disposed on the third passivation layer 117. When the liquid metal or silver paste is injected, by the inkjet process, into a pocket of the temporary organic layer 690 that surrounds the light-emitting element 630, the liquid metal or silver paste may permeate between the light-emitting element 630 and the third passivation layer 117. Thereafter, when a curing process is performed, the temporary metal layer 649 is formed between the light-emitting element 630 and the third passivation layer 117 and between the light-emitting element 630 and the temporary organic layer 690.

Next, with reference to FIG. 7C, a photoresist PR is disposed on the light-emitting element 630 and a temporary metal layer 639. The photoresist PR may be disposed to completely overlap the top surface of the light-emitting element 630 and overlap a part of the top surface of the temporary metal layer 639 adjacent to the light-emitting element 630.

Next, with reference to FIG. 7D, the metal layer 640 is formed by an etching process. As illustrated in FIG. 7C, when the etching process is performed while the photoresist PR is disposed, the first part 641 of the metal layer 640 is formed between the third passivation layer 117 and the light-emitting element 630, and the third part 643 of the metal layer 640 contacts with the entire side surface of the light-emitting element 630, and the second part 642 connecting the first part 641 and the third part 643.

Next, the temporary organic layer 690 is removed. Because the temporary organic layer 690 is a layer temporarily used for the self-assembly process, the temporary organic layer 690 is removed for a subsequent process.

Next, with reference to FIG. 7E, the second planarization layer 618 is formed. The second planarization layer 618 may planarize the light-emitting element 630, the first line 121, and the second line 122.

Next, the pixel electrode PE is formed on the second planarization layer 618.

In the display device 600 according to yet another aspect of the present disclosure, it is possible to increase a bonding strength of the light-emitting element 630 by using a metal layer 640 disposed between the light-emitting element 630 and the third passivation layer 117. Therefore, the display device 600 according to yet another aspect of the present disclosure may prevent an electrical connection between the pixel electrode PE and the lines 121 and 122 caused by a loss of the light-emitting element 630 or the misalignment of the light-emitting element 630.

In addition, in the display device 600 according to yet another aspect of the present disclosure, the metal layer 640 may be disposed to be in contact with the light-emitting element 630, thereby improving luminous efficiency. The light emitted to the lateral portion of the light-emitting element 630 is reflected by the third part 643 of the metal layer 640 contacting the side surface of the light-emitting element 630. That is, because the metal layer 640 is in contact with the side surface of the light-emitting element 630, a distance between the metal layer 640) and the light-emitting element 630 may be minimized. Therefore, the light reflected by the third part 643 of the metal layer 640 may be immediately discharged in the direction of the front surface of the display device 600 through the second electrode 635 of the light-emitting element 630. Alternatively, the light reflected by the third part 643 of the metal layer 640 may be totally reflected in the light-emitting element 630 and then discharged in the direction of the front surface of the display device 600 through the second electrode 635 of the light-emitting element 630. Therefore, the light emitted from the light-emitting element 630 may be reflected in the direction of the front surface of the display device 600 without a loss of light. Therefore, the display device 600 according to yet another aspect of the present disclosure may improve efficiency in extracting light emitted from the light-emitting element 630.

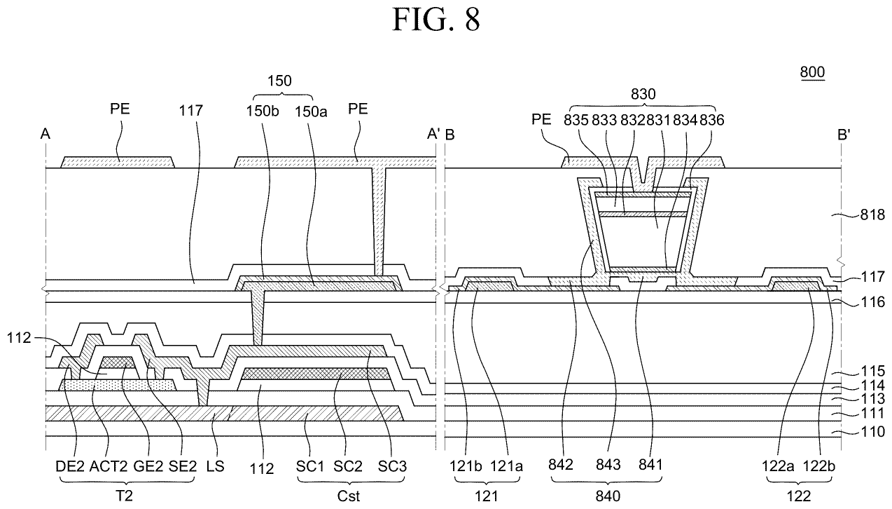

FIG. 8 is a cross-sectional view of a display device according to still yet another aspect of the present disclosure. A display device 800 in FIG. 8 is substantially identical in configuration to the display device 600 in FIGS. 6 to 7E, except for a light-emitting element 830, a second planarization layer 818, and a metal layer 840. Therefore, repeated descriptions of the identical components will be omitted.

The plurality of light-emitting elements 830 is disposed on the third passivation layer 117. With reference to FIG. 6, the plurality of light-emitting elements 830 each includes a first semiconductor layer 831, a light-emitting layer 832, a second semiconductor layer 833, a first electrode 834, a second electrode 835, and a sealing layer 836.

The first semiconductor layer 831 is disposed on the third passivation layer 117, and the second semiconductor layer 833 is disposed on the first semiconductor layer 831. The first semiconductor layer 831 and the second semiconductor layer 833 may formed by doping a particular material with n-type and p-type impurities. For example, the first semiconductor layer 831 and the second semiconductor layer 833 may each be a layer formed by doping a material, such as gallium nitride (GaN), indium aluminum phosphide (InAlP), or gallium arsenic (GaAs) with p-type or n-type impurities. Further, the p-type impurity may be magnesium (Mg), zinc (Zn), beryllium (Be), or the like. The n-type impurity may be silicon (Si), germanium (Ge), tin (Sn), or the like. However, the present disclosure is not limited thereto.

The light-emitting layer 832 is disposed between the first semiconductor layer 831 and the second semiconductor layer 833. The light-emitting layer 832 may emit light by receiving positive holes and electrons from the first semiconductor layer 831 and the second semiconductor layer 833. The light-emitting layer 832 may be configured as a single layer or a multi-quantum well (MQW) structure. For example, the light-emitting layer 832 may be made of indium gallium nitride (InGaN), gallium nitride (GaN), or the like. However, the present disclosure is not limited thereto.

The first electrode 834 is disposed on a bottom surface of the first semiconductor layer 831. The first electrode 834 is an electrode that electrically connects the light-emitting element 830 and the lines 121 and 122. The first electrode 834 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 835 is disposed on the top surface of the second semiconductor layer 833. The second electrode 835 electrically connects the pixel electrode PE and the second semiconductor layer 833. The second electrode 835 may be made of an electrically conductive material, e.g., a transparent conductive material such as indium tin oxide (ITO) or indium zinc oxide (IZO). However, the present disclosure is not limited thereto.

The sealing layer 836 is disposed to at least partially surround the first semiconductor layer 831, the light-emitting layer 832, the second semiconductor layer 833, and the second electrode 835. The sealing layer 836 may be made of an insulating material and protect the first semiconductor layer 831, the light-emitting layer 832, and the second semiconductor layer 833. The sealing layer 836 may be disposed to cover side surfaces of the first semiconductor layer 831, the light-emitting layer 832, and the second semiconductor layer 833. The first electrode 834 and the second electrode 835 may be exposed by the sealing layer 836. Therefore, the pixel electrode PE and the second electrode 835, which are formed subsequently, may be electrically connected.

A cross-section of the light-emitting element 830 may have a shape having a width that increases in a direction from the bottom surface to the top surface. For example, as illustrated in FIG. 8, a cross-section of the light-emitting element 830 may have an inversely trapezoidal shape. That is, in a cross-sectional view, the width of the cross-section may decrease in the order of the second electrode 835, the second semiconductor layer 833, the light-emitting layer 832, the first semiconductor layer 831, and the first electrode 834.

The metal layer 840 is disposed on the lines 121 and 122. Specifically, the metal layer 840 may be provided between the third passivation layer 117 and the light-emitting element 830 and be in contact with the side surface of the light-emitting element 830 and the lines 121 and 122. The metal layer 840 is disposed on the first line 121 and the second line 122 to overlap the first line 121 and the second line 122. In this case, the metal layer 840 is connected to the first clad layer 121b of the first line 121 and the second clad layer 122b of the second line 122 through a contact hole of the third passivation layer 117 disposed outside the light-emitting element 830.

The metal layer 840 includes a first part 841, a second part 842, and a third part 843.

The first part 841 is disposed between the light-emitting element 830 and the third passivation layer 117. Therefore, the first part 841 may be in contact with the bottom surface of the light-emitting element 830, specifically be in contact with the first electrode 834 of the light-emitting element 830. In this case, the first part 841 of the metal layer 840 may serve as a bonding layer for fixing or bonding the light-emitting element 830 to the third passivation layer 117.

The second part 842 may connect the first part 841, the first line 121, and the second line 122. The second part 842 may be connected to the first clad layer 121b of the first line 121 and the second clad layer 122b of the second line 122 through the contact hole of the third passivation layer 117.

The third part 843 may contact the entire side surface of the light-emitting element 830. The third part 843 may be disposed to be in contact with the sealing layer 836 of the light-emitting element 830. In addition, as illustrated in FIG. 8, the third part 843 may be disposed to be in contact with a part of the top surface of the light-emitting element 830.

The metal layer 840 may be formed by a metal inkjet process. For example, the metal layer 840 may be a layer made by curing liquid metal or silver paste (Ag paste).

Next, the second planarization layer 818 is disposed on the light-emitting element 830. The second planarization layer 818 may planarize the upper portion of the substrate 110 on which the first line 121, the second line 122, and the light-emitting element 830 are disposed. The second planarization layer 818, together with the metal layer 840, may fix the light-emitting element 830 onto the substrate 110. Therefore, the second planarization layer 818 may contact the metal layer 840 disposed on the side surface of the light-emitting element 830. The second planarization layer 818 may be configured as a single layer or multilayer and made of an acrylic-based organic material, for example. However, the present disclosure is not limited thereto.

In the display device 800 according to still yet another aspect of the present disclosure, it is possible to increase a bonding strength of the light-emitting element 830 by using a metal layer 840 disposed between the light-emitting element 830 and the third passivation layer 117. Therefore, the display device 800 according to still yet another aspect of the present disclosure may suppress a problem with connection between the pixel electrode PE and the lines 121 and 122 caused by a loss of the light-emitting element 830 or the misalignment of the light-emitting element 830.

In addition, in the display device 800 according to still yet another aspect of the present disclosure, the metal layer 840 may contact the light-emitting element 830, thereby improving luminous efficiency. The light emitted to the lateral portion of the light-emitting element 830 is reflected by the third part 843 of the metal layer 840 on the side surface of the light-emitting element 830. That is, because the metal layer 840 contacts the side surface of the light-emitting element 830, a distance between the metal layer 840 and the light-emitting element 830 may be minimized. Therefore, the light reflected by the third part 843 of the metal layer 840 may be immediately discharged in the direction of the front surface of the display device 800 through the second electrode 835 of the light-emitting element 830. Alternatively, the light reflected by the third part 843 of the metal layer 840 may be totally reflected in the light-emitting element 830 and then discharged in the direction of the front surface of the display device 800 through the second electrode 835 of the light-emitting element 830. Therefore, the light emitted from the light-emitting element 830 may be reflected in the direction of the front surface of the display device 800 without a loss of light. In addition, an angle defined between the third part 843 of the metal layer 840, which contacts the side surface of the light-emitting element 630, and the first part 841 of the metal layer 840 may be an obtuse angle. Therefore, the light emitted from the light-emitting element 830 may be more efficiently reflected in the direction of the front surface of the display device 800. Therefore, the display device 800 according to still yet another aspect of the present disclosure may improve efficiency in extracting light emitted from the light-emitting element 830.

The aspects of the present disclosure may also be described as follows:

According to an aspect of the present disclosure, a display device includes: a substrate including a plurality of sub-pixels: a first line and a second line disposed in the plurality of sub-pixels on the substrate and spaced apart from each other: a passivation layer covering the first line and the second line: a light-emitting element on the passivation layer above the first line and the second line, and including a first electrode, a first semiconductor layer, a light-emitting layer, a second semiconductor layer, and a second electrode; and a metal layer between the passivation layer and the light-emitting element and connected to the first line and the second line.

The metal layer may be partially in contact with a bottom surface and a side surface of the light-emitting element.

The metal layer may be connected to the first line and the second line through a contact hole of the passivation layer.

The display device may further include a planarization layer planarizing an upper portion of the light-emitting element. The planarization layer and the passivation layer may include an opening exposing top surfaces of the first line and the second line and having a side surface that is inclined.

The display device may further include a reflective layer on the side surface of the opening.

The reflective layer may be disposed on at least a portion of the side surface of the opening adjacent to the light-emitting element.

The display device may further include a filling layer configured to fill the opening on which the reflective layer is disposed. The filling layer may be made of a black material.

The reflective layer may be disposed on a portion of the side surface of the opening that faces the light-emitting element.

The display device may further include a filling layer configured to fill the opening on which the reflective layer is disposed. The filling layer may be made of a transparent material.

Each of the first line and the second line include: a conductive layer: and a clad layer covering the conductive layer and extending toward the light-emitting element. The opening may overlap the conductive layer.

The display device may further include: a planarization layer covering the first line and the second line while surrounding the light-emitting element and including an opening having a side surface that is inclined: and a reflective layer disposed on the side surface of the opening.

The reflective layer may be connected to the metal layer.

The reflective layer may be made of the same material as the metal layer.

The metal layer may be disposed to be in contact with both a bottom surface and a side surface of the light-emitting element.

A cross-section of the light-emitting element may have a shape having a width that increases in a direction from a bottom surface to a top surface.

A cross-section of the light-emitting element may have a shape having a width that decreases in a direction from a bottom surface to a top surface.

The display may further include a planarization layer planarizing upper portions of the first line, the second line, and the light-emitting element. The planarization layer may be in contact with the metal layer disposed on the side surface of the light-emitting element.

The metal layer may be made by curing liquid metal or silver paste (Ag paste).

Although the aspects of the present disclosure have been described in detail with reference to the accompanying drawings, the present disclosure is not limited thereto and may be embodied in many different forms without departing from the technical concept of the present disclosure. Therefore, the aspects of the present disclosure are provided for illustrative purposes only but not intended to limit the technical concept of the present disclosure. The scope of the technical concept of the present disclosure is not limited thereto. Therefore, it should be understood that the above-described aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a plurality of sub-pixels;
a driving circuit on the substrate;
a plurality of lines electrically connected to the driving circuit;
a plurality of protrusions disposed over the plurality of lines;
a plurality of light-emitting elements disposed on the plurality of protrusions;
a metal layer between at least one protrusion and at least one light-emitting element, and electrically connecting the driving circuit to the at least one light-emitting element; and
a planarization layer;
a pixel electrode electrically connected to the at least one light-emitting element;
a first contact hole formed in the planarization layer and disposed over the at least one light emitting element and exposing a first surface of the at least one light emitting element.

2. The display device of claim 1, wherein the pixel electrode contacts a first electrode of the at least one light emitting element through the first contact hole.

3. The display device of claim 2, wherein the pixel electrode is disposed on the planarization layer.

4. The display device of claim 3, wherein the at least one light emitting element comprises a cover over at least a portion of the first surface of the light emitting element, wherein an exposed portion of the first surface of the at least one light emitting element contacts the pixel electrode.

5. The display device of claim 1, further comprising a second contact hole adjacent to the at least one light emitting element and having a depth greater than the first contact hole.

6. The display device of claim 5, wherein the second contact hole comprises a black filling material.

7. The display device of claim 5, further comprising an emission enhancement layer disposed between the black filling material and the at least one light emitting element.

8. The display device of claim 5, wherein the black filling material covers a portion of a surface of the planarization layer.

9. The display device of claim 5, wherein the black filling material blocks light from an adjacent light emitting element.

10. The display device of claim 1, wherein a second surface of the at least one light emitting element is electrically connected to the driving circuit through the metal layer.

11. The display device of claim 1, wherein the metal layer transmits a high potential voltage or a low potential voltage.

12. The display device of claim 1, wherein each protrusion of the plurality of protrusion comprises a recesses portion for receiving a metal paste, wherein the metal paste is cured to bond and electrically connects the at least one light emitting element to the metal layer.

13. The display device of claim 1, wherein each protrusion of the plurality of protrusion comprises a width greater than a width of the at least one side surface of the at least one light emitting element.

14. The display device of claim 1, further comprising a plurality of insulating layers disposed between the driving circuit and the protrusion.

15. The display device of claim 14, wherein the plurality of lines are disposed between the protrusion and the plurality of insulating layers.

16. The display device of claim 1, wherein at least one of the plurality of lines are connected to an emission enhancement layer.

17. The display device of claim 16, wherein the emission enhancement layer is formed in a second contact hole.

18. A method for manufacturing a display device, comprising:
depositing a metal layer on a substrate, the metal layer comprising at a first line and a second line;
forming a passivation layer over the metal layer;
forming a temporary layer over the passivation layer with a plurality of exposed regions for light emitting elements;
disposing a plurality of light emitting elements into the plurality of exposed regions;
applying a liquid metal into each exposed region and curing the liquid metal into a metal to bond each light emitting element to the at least the passivation layer;
removing the temporary layer; and
forming a planarization layer over the entire substrate.

19. The method of claim 18, further comprising:
forming a photoresist mask over each exposed region; and
etching at least a portion of the metal, wherein the light emitting element is exposed in a single light emission direction.

20. A display device comprising:
a substrate including a plurality of sub-pixels;
a first line and a second line disposed in the plurality of sub-pixels on the substrate and separated from each other;
a passivation layer covering the first line and the second line;
a light-emitting element on the passivation layer above the first line and the second line; and
a metal layer between the passivation layer and the light-emitting element and connected to the first line and the second line.

21. The display device of claim 20, wherein the metal layer contacts a bottom surface and a side surface of the light-emitting element.

22. The display device of claim 20, wherein the metal layer is connected to the first line and the second line through a contact hole of the passivation layer.

23. The display device of claim 20, further comprising:
a planarization layer planarizing an upper portion of the light-emitting element,
wherein the planarization layer and the passivation layer include an opening exposing top surfaces of the first line and the second line and having an inclined side surface.

24. The display device of claim 23, further comprising:
a reflective layer on the side surface of the opening.

25. The display device of claim 24, wherein the reflective layer is disposed on at least a portion of the side surface of the opening adjacent to the light-emitting element.

26. The display device of claim 25, further comprising:
a filling layer configured to fill the opening,
wherein the filling layer comprises a black material.

27. The display device of claim 24, wherein the reflective layer is disposed on a portion of the side surface of the opening that faces the light-emitting element.

28. The display device of claim 27, further comprising:
a filling layer configured to fill the opening,
wherein the filling layer comprises a transparent material.

29. The display device of claim 23, wherein each of the first line and the second line includes:
a conductive layer; and
a clad layer covering the conductive layer and extending toward the light-emitting element, and
wherein the opening overlaps the conductive layer.

30. The display device of claim 20, further comprising:
a planarization layer covering the first line and the second line while surrounding the light-emitting element and including an opening having an inclined side surface; and
a reflective layer disposed on the side surface of the opening.

31. The display device of claim 30, wherein the reflective layer is connected to the metal layer.

32. The display device of claim 30, wherein the reflective layer comprises a same material as the metal layer.

33. The display device of claim 20, wherein the metal layer contacts a bottom surface and a side surface of the light-emitting element.

34. The display device of claim 33, wherein a cross-section of the light-emitting element comprises a shape having a width that increases in a direction from a bottom surface to a top surface.

35. The display device of claim 33, wherein a cross-section of the light-emitting element has a shape having a width that decreases in a direction from a bottom surface to a top surface.

36. The display device of claim 33, further comprising:
a planarization layer planarizing upper portions of the first line, the second line, and the light-emitting element,
wherein the planarization layer contacts the metal layer disposed on the side surface of the light-emitting element.

37. The display device of claim 1, wherein the metal layer is formed by curing liquid metal or silver paste (Ag paste).
